(19) United States
(12) Patent Application Publication
(10) Pub. No.: US 2008/0122429 A1
(43) Pub. Date: May 29, 2008

(54) CURRENT MEASURING CIRCUIT FOR TWO PHASE ELECTROMOTOR

(75) Inventor: Young Hoon CHO, Gyeonggi-do (KR)

Correspondence Address: GREENBLUM & BERNSTEIN, P.L.C., 1950 ROLAND CLARKE PLACE, RESTON, VA, 20191, US

(73) Assignee: HYUNDAI MOBIS CO., LTD., Seoul (KR)

(21) Appl. No.: 11/669,392

(22) Filed: Jan. 31, 2007

(30) Foreign Application Priority Data
Nov. 24, 2006 (KR) 10-2006-0116905

(51) Int. Cl. G01R 19/00

(52) U.S. Cl. 324/107

(57) ABSTRACT

The present invention relates to a current measuring circuit for a two phase electromotor, and more particularly, to a current measuring circuit for a two phase electromotor that is capable of measuring two phase currents of the two phase electromotor using one current measuring sensor.

A current measuring circuit for a two phase electromotor according to an aspect of the present invention includes first and second capacitors that are connected in series to each other, first and second inductors that are connected in parallel to each other between the first and second capacitors connected in series to each other, and are supplied with two phase currents of the two phase electromotor, respectively, a first switch that is connected to the first inductor, and a current measuring sensor that is common provided among the first capacitor, the first switch, and the first inductor and measures the currents supplied to the first and second inductors.

### CROSS-REFERENCE TO RELATED APPLICATIONS

The present application is based on, and claims priority from, Korean Application Serial Number 10-2006-0116905, filed on Nov. 24, 2006, the disclosure of which is hereby incorporated by reference herein in its entirety.

### FIELD OF THE INVENTION

The present invention relates to a current measuring circuit for a two phase electromotor, and more particularly, to a current measuring circuit for a two phase electromotor that is capable of measuring two phase currents of the two phase electromotor using one current measuring sensor.

### BACKGROUND OF THE INVENTION

FIG. 1 is a circuit diagram illustrating a current measuring circuit for a two phase electromotor according to the related art.

Referring to FIG. 1, the current measuring circuit for the two phase electromotor according to the related art includes first and second capacitors C1 and C2 that are connected in series to each other, first and second inductors L1 and L2 that are connected in parallel to each other between first and second capacitors C1 and C2 and are supplied with two phase currents of the two phase electromotor, respectively, first and second switch elements T11 and T12 that are connected in series to each other and are connected to first inductor L1, third and fourth switch elements T21 and T22 that are connected in series to each other and are connected to second inductor L2, a first current measuring sensor S1 that measures a-phase current Ia between the two phase currents of the two phase electromotor supplied to first inductor L1, and a second current measuring sensor S2 that measures the b-phase current Ib between the two phase currents of the two phase electromotor supplied to second inductor L2. Among first to fourth switch elements T11, T12, T21, and T22, first and third switch elements T11 and T21 are connected in parallel to each other and are connected to first capacitor C1. Further, among first to fourth switch elements T11, T12, T21, and T22, second and fourth switch elements T12 and T22 are connected in parallel to each other and are connected to second capacitor C2.

The current measuring circuit for the two phase electromotor according to the related art measures a and b-phase currents Ia and Ib of the two phase electromotor flowing through first and second inductors L1 and L2 by first and second current measuring sensors S1 and S2, respectively. Therefore, the current measuring circuit for the two phase electromotor according to the related art can directly and easily measure a and b-phase currents Ia and Ib of the two phase electromotor flowing through first and second inductors L1 and L2, respectively.

In addition, the two phase electromotor uses a-phase current Ia and b-phase current Ib measured by the current measuring circuit as software detecting currents in an ECU.

However, even though the current measuring circuit for the two phase electromotor according to the related art can directly and easily measure a and b-phase currents Ia and Ib of the two phase electromotor flowing through first and second inductors L1 and L2, first and second current measuring sensors S1 and S2 need to be provided, which increases the manufacturing cost. In addition, the current measuring circuit for the two phase electromotor according to the related art measures a and b-phase currents Ia and Ib of the two phase electromotor using different first and second current measuring sensors S1 and S2, respectively, which causes error due to the offset and scaling difference between the first and second current measuring sensors S1 and S2.

Different from a three phase electromotor driving system, the two phase electromotor is a system that has advantages having high reliability and low manufacturing cost. Accordingly, it is necessary to reduce the manufacturing cost and prevent the error in the current measuring circuit for the two phase electromotor.

### SUMMARY OF THE INVENTION

Embodiments of the present invention provides a current measuring circuit for a two phase electromotor that is capable of measuring two phase currents of the two phase electromotor using one current measuring sensor so as to reduce the manufacturing cost, and preventing error from occurring.

A current measuring circuit for a two phase electromotor according to an embodiment of the present invention includes first and second capacitors that are connected in series to each other. First and second inductors are connected in parallel to each other between the first and second capacitors connected in series to each other, and are supplied with two phase currents of the two phase electromotor, respectively. A first switch is connected to the first inductor, and a current measuring sensor is common provided among the first capacitor, the first switch, and the first inductor and measures the currents supplied to the first and second inductors.

The current measuring circuit may further include a second switch element that is connected in series to the first switch element, and third and fourth switch elements that are connected in series to each other and are connected to the second inductor. The first and third switch elements may be connected in parallel to each other and be connected to the first capacitor, and the second and fourth switch elements may be connected in parallel to each other and be connected to the second capacitor.

The current measuring sensor may measure a current that is obtained by subtracting a current according to a direct current voltage charged between the first and second capacitors by the current supplied to the first inductor.

The current measuring sensor may measure the current flowing through the second inductor when the first switch and the third switch are turned on and the second switch and the fourth switch are turned off, and measure an inverse current of the current flowing through the first inductor when the second switch and the fourth switch are turned on and the first switch and the third switch are turned off.

When the second switch and the fourth switch are turned on and the first switch and the third switch are turned off, the inverse current of the current measured by the current measuring sensor may be determined as the current flowing through the first inductor.

When the first switch and the fourth switch are turned on and the second switch and the third switch are turned off, and when the second switch and the third switch are turned on and the first switch and the fourth switch are turned off, the current measured by the current measuring sensor may be ignored.

A current measuring circuit for a two phase electromotor according to another embodiment of the present invention includes first and second capacitors that are connected in series to each other, First and second inductors are connected in parallel to each other between the first and second capacitors connected in series to each other, and are supplied with two phase currents of the two phase electromotor, respectively. A third switch element is connected to the second inductor. A current measuring sensor is common provided among the second capacitor, the third switch, and the second inductor, and measures the currents supplied to the first and second inductors.

The current measuring circuit may further include first and second switch elements that are connected in series to each other and are connected to the first inductor, and a fourth switch element that is connected in series to the third switch element. The first and third switch elements may be connected in parallel to each other and be connected to the first capacitor, and the second and fourth switch elements may be connected in parallel to each other and be connected to the second capacitor.

The current measuring sensor may measure a current that is obtained by subtracting a current according to a direct current voltage charged between the first and second capacitors by the current supplied to the second inductor.

The current measuring sensor may measure the current flowing through the first inductor when the first switch and the third switch are turned on and the second switch and the fourth switch are turned off, and measure an inverse current of the current flowing through the second inductor when the second switch and the fourth switch are turned on and the first switch and the third switch are turned off.

When the second switch and the fourth switch are turned on and the first switch and the third switch are turned off, the inverse current of the current measured by the current measuring sensor may be determined as the current flowing through the second inductor.

When the first switch and the fourth switch are turned on and the second switch and the third switch are turned off, and when the second switch and the third switch are turned on and the first switch and the fourth switch are turned off, the current measured by the current measuring sensor may be ignored.

### BRIEF DESCRIPTION OF THE DRAWINGS

For a better understanding of the nature and objects of the present invention, reference should be made to the following detailed description with the accompanying drawings, in which:

FIG. 1 is a circuit diagram of a current measuring circuit for a two phase electromotor according to the related art;

FIGS. 2A to 2C are diagrams illustrating a current measuring circuit for a two phase electromotor that includes one current measuring sensor, and an operation of the current measuring circuit;

FIG. 3 is a diagram illustrating a current measuring circuit for a two phase electromotor according to an embodiment of the present invention;

FIG. 4 is a diagram illustrating a method of measuring a two phase current using a current measuring circuit for a two phase electromotor according to an embodiment of the present invention;

FIGS. 5A and 5B are diagrams illustrating an actual current of a two phase electromotor, and a current of the two phase electromotor that is measured by using a current measuring circuit for a two phase electromotor according to an embodiment of the present invention; and

FIG. 6 is a diagram illustrating a current measuring circuit for a two phase electromotor according to another embodiment of the present invention.

### DETAILED DESCRIPTION OF THE PREFERRED EMBODIMENTS

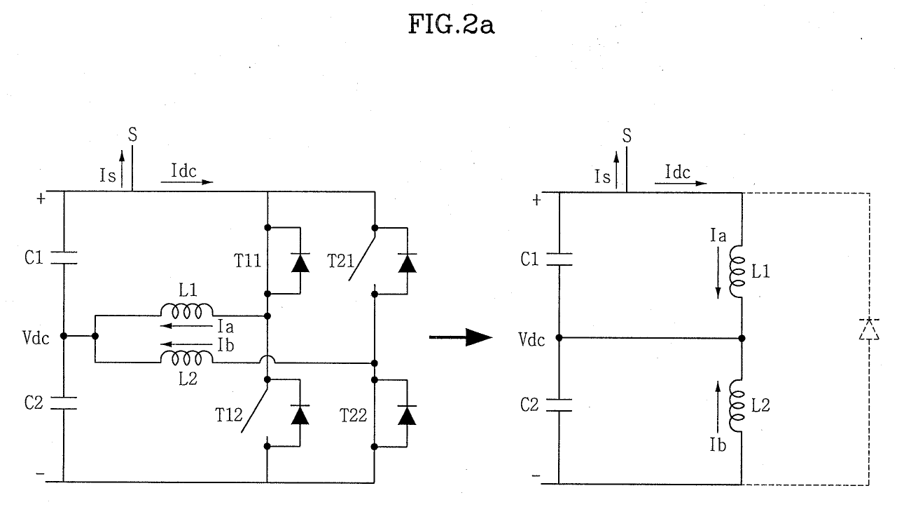

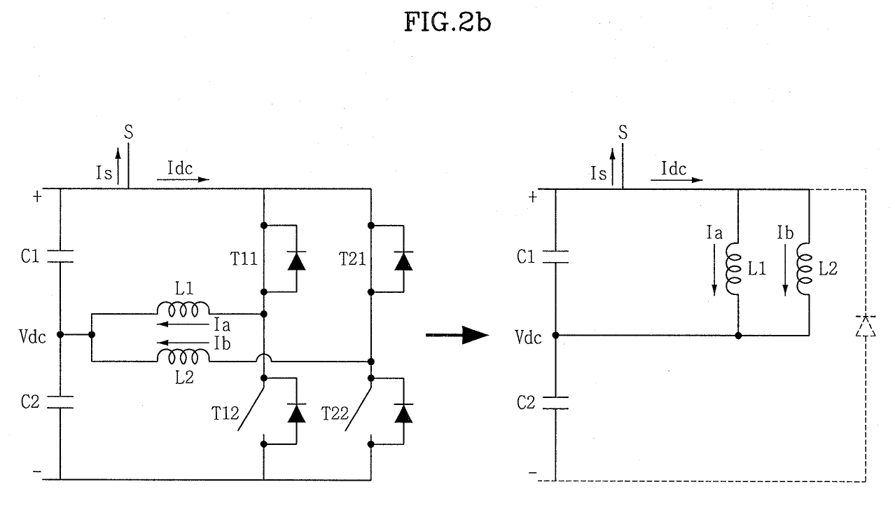

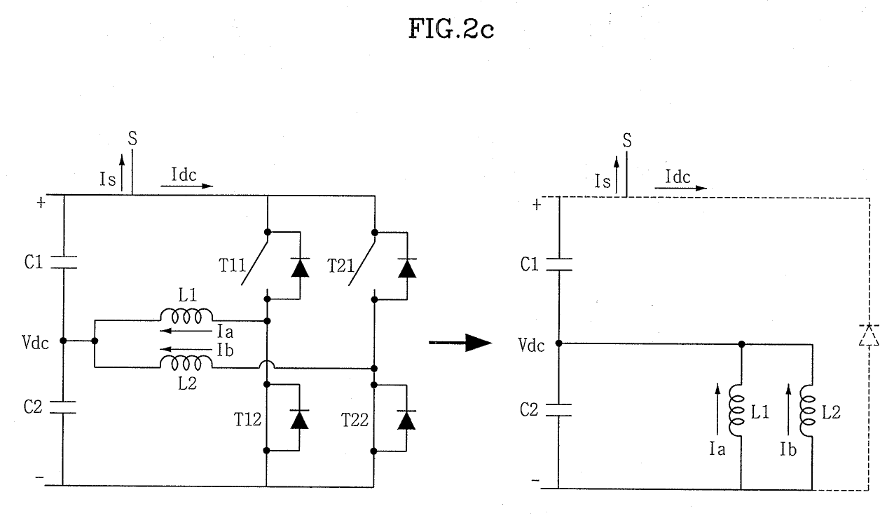

Hereinafter, the preferred embodiments of the present invention will be described with reference to FIGS. 2A to 6.

FIGS. 2A to 2C are diagrams illustrating a current measuring circuit for a two phase electromotor that includes one current measuring sensor, and the operation of the current measuring circuit.

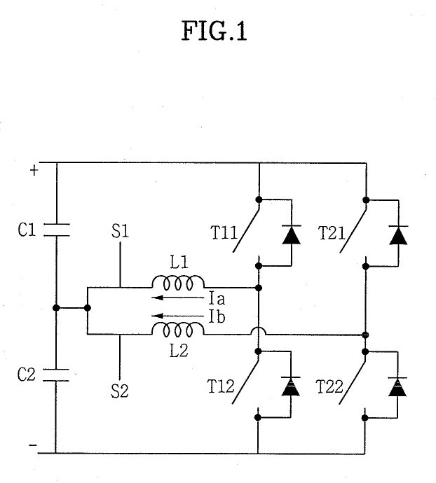

In the current measuring circuit for a two phase electromotor that includes one current measuring sensor shown in FIGS. 2A to 2C, the description of the same structure as that in FIG. 1 will be omitted.

Referring to FIGS. 2A to 2C, the current measuring circuit for the two phase electromotor that includes one current measuring sensor S includes one current measuring sensor S that is common provided between a first capacitor C1 and first and third switch elements T11 and T21. Therefore, in the current measuring circuit for the two phase electromotor that includes one current measuring sensor, current Is that is measured by current measuring sensor S is a current Idc according to a direct voltage Vdc that is charged between the first and second capacitors C1 and C2.

In the current measuring circuit for the two phase electromotor that includes one current measuring sensor, in the case of a first mode in which first switch T11 and a fourth switch T22 are turned on and a second switch T12 and third switch T21 are turned off, current measuring sensor S measures the a-phase current Ia of the two phase electromotor as current Idc according to direct voltage Vdc that is charged between first and second capacitors C1 and C2. Referring to FIG. 2A, current Idc according to direct voltage Vdc that is charged between first and second capacitors C1 and C2 is the same as a-phase current Ia of the two phase electromotor. Accordingly, current measuring sensor S measures a-phase current Ia of the two phase electromotor as current Idc according to direct current voltage Vdc that is charged between first and second capacitors C1 and C2. In the current measuring circuit for the two phase electromotor that includes one current measuring sensor, in the case of a second mode in which second switch T12 and third switch T21 are turned on and first switch T11 and fourth switch T22 are turned off, current measuring sensor S measures b-phase current Ib of the two phase electromotor supplied to a second inductor L2 as current Idc according to direct voltage Vdc that is charged between first and second capacitors C1 and C2.

Further, in the current measuring circuit for the two phase electromotor that includes one current measuring sensor, in the case of a third mode in which first switch T11 and third switch T21 are turned on and second switch T12 and fourth switch T22 are turned off, current measuring sensor S measures a total current between a-phase current Ia of the two phase electromotor supplied to first inductor L1 and b-phase current Ib of the two phase electromotor supplied to second inductor L2 as current Idc according to direct voltage Vdc that is charged between first and second capacitors C1 and C2. Referring to FIG. 2B, current Idc according to direct voltage Vdc that is charged between first and second capacitors C1 and C2 is the same as the total current between a-phase current Ia of the two phase electromotor and b-phase current Ib of the two phase electromotor. Accordingly, current measuring sensor S measures a total current between a-phase current Ia of the two phase electromotor supplied to first inductor L1 and b-phase current Ib of the two phase electromotor supplied to second inductor L2 as current Idc according to direct current voltage Vdc that is charged between first and second capacitors C1 and C2.

In addition, in the current measuring circuit for the two phase electromotor that includes one current measuring sensor, in the case of a fourth mode in which second switch T12 and fourth switch T22 are turned on and first switch T11 and third switch T21 are turned off, current measuring sensor S cannot measure the current, as shown in FIG. 2C.

It can be summarized in Table 1.

TABLE 1

| Mode | Is |
|---|---|
| FIRST MODE | Ia |
| SECOND MODE | Ib |
| THIRD MODE | Ia + Ib |
| FOURTH MODE | 0 |

As such, the current measuring circuit for the two phase electromotor, which includes one current measuring sensor S between first capacitor C1 and first and third switch elements T11 and T21, measures current Idc according to direct current voltage Vdc that is charged between first and second capacitors C1 and C2, in the cases of the first to third modes. Specifically, in the case of the first mode, current Is that is measured by the current measuring sensor is a-phase current Ia of the two phase electromotor, and in the case of the second mode, current Is that is measured by the current measuring sensor is b-phase current Ib of the two phase electromotor. Therefore, a-phase current Ia and b-phase current Ib of the two phase electromotor can be measured. However, in the case of the third mode, since current Is that is measured by the current measuring sensor corresponds to the total current between a-phase current Ia and b-phase current Ib of the two phase electromotor, it is not possible to measure each of a-phase current Ia and b-phase current Ib of the two phase electromotor. In the case of the fourth mode, it is not possible to measure current Idc according to direct current voltage Vdc that is charged between first and second capacitors C1 and C2, and thus it is not possible to measure each of a-phase current Ia and b-phase current Ib of the two phase electromotor.

Meanwhile, the general current measuring circuit for the two phase electromotor is driven in the first to fourth modes, but the first mode and the second mode may be generated or not generated during one period according to a phase of a-phase current Ia of the two phase electromotor and a phase of b-phase current Ib of the two phase electromotor. However, the third mode and the fourth mode are always generated during one period according to the phase of a-phase current Ia of the two phase electromotor and the phase of b-phase current Ib of the two phase electromotor.

Therefore, it is difficult to measure a-phase current Ia and b-phase current Ib of the two phase electromotor by using the current measuring circuit for the two phase electromotor that includes one current measuring sensor S that is connected between first and third switch elements T11 and T21, and first capacitor C.

The above-described problem is the same even not only in the case of including current measuring sensor S that is common provided between first capacitor C1 and first and third switch elements T11 and T21 as shown in FIGS. 2A to 2C but also the case of including current measuring sensor S that is common provided between second capacitor C1, and second and fourth switch elements T12 and T22.

The current measuring circuit for the two phase electromotor according to the embodiment of the present invention is based on when the general current measuring circuit for the two phase electromotor is driven mainly in the third and fourth modes.

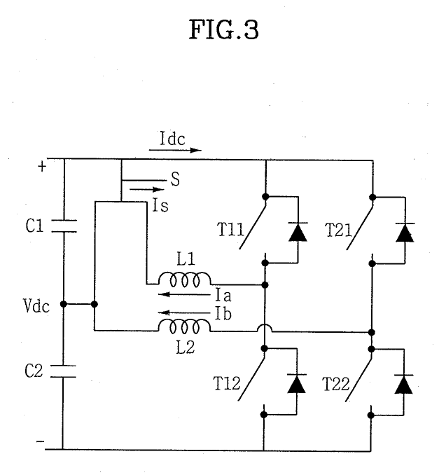

Hereinafter, the current measuring circuit for the two phase electromotor according to the embodiment of the present invention will be described with reference to FIG. 3.

In the current measuring circuit for the two phase electromotor according to the embodiment of the invention shown in FIG. 3, the same structure as in FIG. 1 will be omitted.

Referring to FIG. 3, the current measuring circuit for the two phase electromotor according to the embodiment of the invention includes current measuring sensor S that is common provided among first capacitor C1, first and third switch elements T11 and T21, and first inductor T1. Accordingly, current Is, which is measured by current measuring sensor S of the current measuring circuit for the two phase electromotor according to the embodiment of the present invention, is current (Is=Idc−Ia) that is obtained by subtracting current Idc according to direct current voltage Vdc charged between first and second capacitors C1 and C2 by a-phase current Ia of the two phase electromotor.

In the current measuring circuit for the two phase electromotor according to the embodiment of the present invention, in the case of the first mode in which first switch T11 and fourth switch T22 are turned on and second switch T12 and third switch T21 are turned off, current measuring sensor S measures 0 as current (Is=Idc−Ia) that is obtained by subtracting current Idc according to direct current voltage Vdc charged between first and second capacitors C1 and C2 by a-phase current Ia of the two phase electromotor. Specifically, in the first mode, current Idc according to direct current voltage Vdc that is charged between first and second capacitors C1 and C2 is a-phase current Ia of the two phase electromotor (see FIG. 2A). Thus, in the first mode, current Is, which is measured by current measuring sensor S of the current measuring circuit for the two phase electromotor according to the embodiment of the present invention, is 0 (Is=Ia−Ia). In addition, in the current measuring circuit for the two phase electromotor according to the embodiment of the present invention, in the case of the second mode in which second switch T12 and third switch T21 are tuned on and first switch T11 and fourth switch T22 are turned off, current measuring sensor S measures a current obtained by subtracting b-phase current Ib of the two phase electromotor by a-phase current Ia of the two phase electromotor as current (Is=Idc−Ia) obtained by subtracting current Idc according to direct current voltage Vdc charged between first and second capacitors C1 and C2 by a-phase current Ia of the two phase electromotor. Specifically, in the second mode, current Idc according to direct current voltage Vdc that is charged between first and second capacitors C1 and C2 is b-phase current Ib of the two phase electromotor. Thus, in the second mode, current Is, which is measured by current measuring sensor S of the current measuring circuit for the two phase electromotor according to the embodiment of the present invention, is 0 (Is=Ib−Ia).

Furthermore, in the current measuring circuit for the two phase electromotor according to the embodiment of the present invention, in the case of the third mode in which first switch T11 and third switch T21 are turned on and second switch T12 and fourth switch T22 are turned off, current measuring sensor S measures b-phase current Ib of the two phase electromotor as current (Is=Idc−Ia) obtained by subtracting current Idc according to direct current voltage Vdc charged between first and second capacitors C1 and C2 by a-phase current Ia of the two phase electromotor. Specifically, in the third mode, current Idc according to direct current voltage Vdc that is charged between first and second capacitors C1 and C2 is the sum between a-phase current Ia of the two phase electromotor and b-phase current Ib of the two phase electromotor (see FIG. 2B). Thus, in the third mode, current Is, which is measured by current measuring sensor S of the current measuring circuit for the two phase electromotor according to the embodiment of the present invention, is b-phase current Ib (Is=Ia+Ib−Ia) of the two phase electromotor.

In addition, in the current measuring circuit for the two phase electromotor according to the embodiment of the present invention, in the case of a fourth mode in which second switch T12 and fourth switch T22 are turned on and first switch T11 and third switch T21 are turned off, current measuring sensor S measures an inverse current −Ia of a-phase current Ia of the two phase electromotor as current (Is=Idc−Ia) obtained by subtracting current Idc according to direct current voltage Vdc charged between first and second capacitors C1 and C2 by a-phase current Ia of the two phase electromotor. Specifically, in the fourth mode, current Idc according to direct current voltage Vdc that is charged between first and second capacitors C1 and C2 is 0 (see FIG. 2C). Thus, in the fourth mode, current Is, which is measured by current measuring sensor S of the current measuring circuit for the two phase electromotor according to the embodiment of the present invention, is inverse current −Ia (Is=0−Ia) of a-phase current Ia of the two phase electromotor. Accordingly, the current measuring circuit for the two phase electromotor according to the embodiment of the present invention measures an inverse current of the current measured in the fourth mode, such that current Is measured by current measuring sensor S in the fourth mode becomes a-phase current Ia of the two phase electromotor.

It can be summarized in Table 2.

TABLE 2

| Mode | Idc | Is (Idc − Ia) |
|---|---|---|
| First mode | Ia | 0 (Ia − Ia) |
| Second mode | Ib | Ib − Ia |
| Third mode | Ia + Ib | Ib (Ia − Ib − Ia) |
| Fourth mode | 0 | −Ia (0 − Ia) |

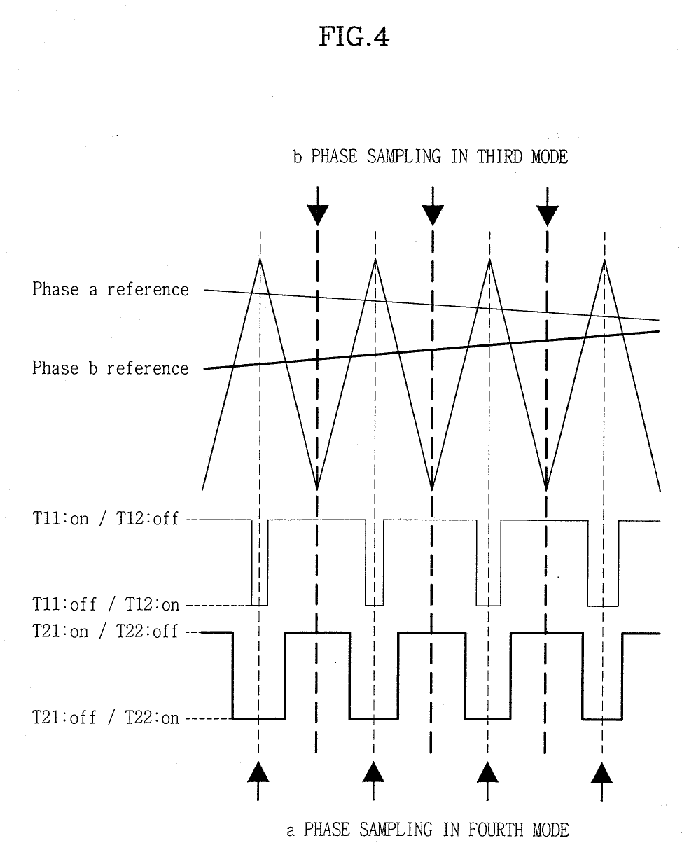

As such, the current measuring circuit for the two phase electromotor according to the embodiment of the present invention includes one current measuring sensor S that is common provided among first capacitor C1, first and third switch elements T11 and T21, and first inductor T1. As shown in FIG. 4, the current measuring circuit for the two phase electromotor according to the embodiment of the present invention measures b-phase current Ib of the two phase electromotor in the third mode in which first switch T11 and third switch T21 are turned on and second switch T12 and fourth switch T22 are turned off, and measures a-phase current Ia for the two phase electromotor in the fourth mode in which second switch T12 and fourth switch T22 are turned on and first switch T11 and third switch T21 are turned off. Therefore, the current measuring circuit for the two phase electromotor according to the embodiment of the present invention measures a-phase current Ia of the two phase electromotor and b-phase current Ib of the two phase electromotor by using one current measuring sensor S, and thus the manufacturing cost can be reduced and the error can be prevented from occurring.

The current measuring circuit for the two phase electromotor according to the embodiment of the present invention cannot measure a-phase current Ia of the two phase electromotor and b-phase current Ib for the two phase electromotor in the first and second modes. However, as shown in FIG. 4, the general current measuring circuit for the two phase electromotor is driven in the third and fourth modes. Thus, even when the current measuring circuit for the two phase electromotor according to the embodiment of the present invention cannot measure a-phase current Ia and b-phase current Ib of the two phase electromotor in the first and second modes, it is difficult to measure a-phase current Ia and b-phase current Ib of the two phase electromotor.

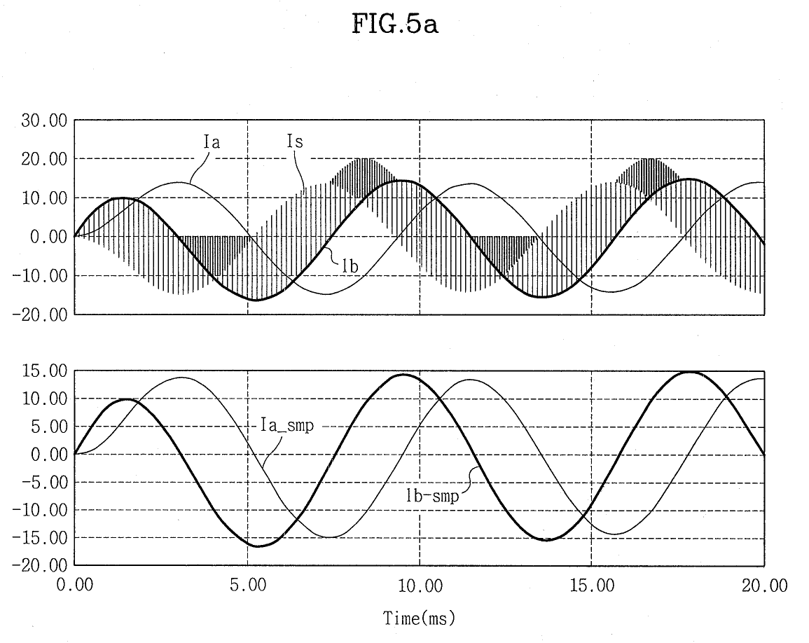

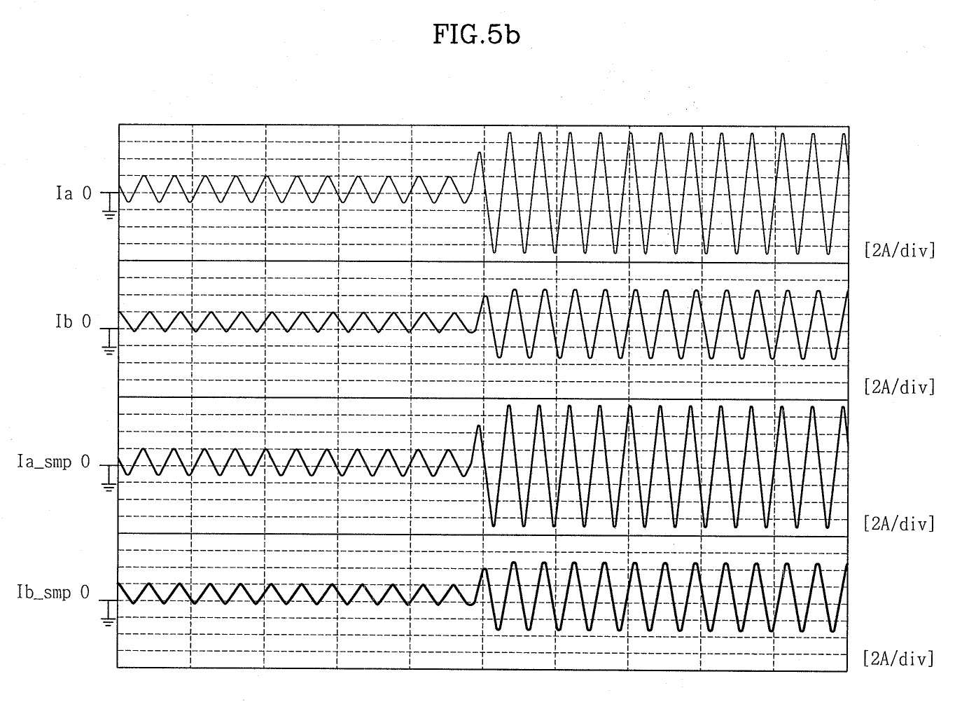

FIGS. 5A to 5B are diagrams illustrating the a-phase current Ia_smp and the b phase electromotor Ib_smp of the two phase electromotor that are sampled on the basis of actual a-phase current Ia of the two phase electromotor, actual b-phase current Ib of the two phase electromotor, current Is measured by current measuring sensor S of the current measuring circuit for the two phase electromotor according to the embodiment of the present invention, and current Is measured by current measuring sensor S according to the embodiment of the present invention.

Referring to FIGS. 5A and 5B, it can be understood that a-phase current Ia_smp and b phase electromotor Ib_smp of the two phase electromotor, which are sampled on the basis of current Is measured by current measuring sensor S according to the embodiment of the present invention, are similar to actual a-phase current Ia and actual b-phase current Ib of the two phase electromotor.

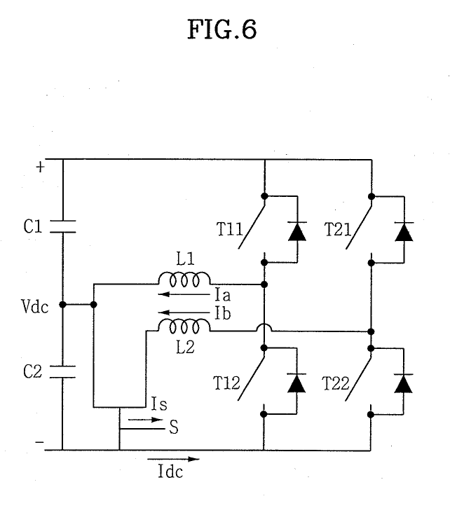

FIG. 6 is a diagram illustrating a current measuring circuit for a two phase electromotor according to another embodiment of the present invention.

Referring to FIG. 6, the current measuring circuit for the two phase electromotor according to another embodiment of the present invention is different from the current measuring circuit for the two phase electromotor according to the embodiment of the present invention in that current measuring sensor S, which is common provided among the second capacitor C2, second and fourth switch elements T12 and T22, and second inductor T2, is provided. Accordingly, current Is, which is measured by current measuring sensor S of the current measuring circuit for the two phase electromotor according to another embodiment of the present invention, corresponds to current (Is=Idc−Ib) obtained by current Idc according to direct current voltage Vdc charged between first and second capacitors C1 and C2 by b-phase current Ib of the two phase electromotor.

When the current measuring circuit for the two phase electromotor according to another embodiment of the present invention is compared with the current measuring circuit for the two phase electromotor according to the embodiment of the present invention, they are the same in the components, except for the location where current measuring sensor S is inserted. Therefore, the components are not described.

Further, the operation of the current measuring circuit for the two phase electromotor according to another embodiment of the present invention is the same as that of the current measuring circuit for the two phase electromotor according to the embodiment of the present invention. Thus, the operation of the current measuring circuit for the two phase electromotor according to another embodiment of the present invention is not described.

As described above, since the current measuring circuit for the two phase electromotor according to the embodiment of the present invention measures the a-phase current and the b-phase current for the two phase electromotor, the manufacturing cost can be reduced, and errors can be prevented from occurring.

1. A current measuring circuit for a two phase electromotor, comprising:
first and second capacitors that are connected in series to each other;
first and second inductors that are connected in parallel to each other between the first and second capacitors connected in series to each other, and are supplied with two phase currents of the two phase electromotor, respectively;
a first switch that is connected to the first inductor; and
a current measuring sensor that is commonly provided among the first capacitor, the first switch, and the first inductor and measures currents supplied to the first and second inductors.

2. The current measuring circuit as defined in claim 1, further comprising:
a second switch that is connected in series to the first switch;
third and fourth switches that are connected in series to each other and are connected to the second inductor,
wherein the first and third switches are connected in parallel to each other and are connected to the first capacitor, and
the second and fourth switches are connected in parallel to each other and are connected to the second capacitor.

3. The current measuring circuit as defined in claim 1, wherein the current measuring sensor measures a current that is obtained by subtracting a current according to a direct current voltage charged between the first and second capacitors by the current supplied to the first inductor.

4. The current measuring circuit as defined in claim 2, wherein the current measuring sensor measures the current flowing through the second inductor when the first switch and the third switch are turned on and the second switch and the fourth switch are turned off, and measures an inverse current of the current flowing through the first inductor when the second switch and the fourth switch are turned on and the first switch and the third switch are turned off.

5. The current measuring circuit as defined in claim 4, wherein, when the second switch and the fourth switch are turned on and the first switch and the third switch are turned off, the inverse current of the current measured by the current measuring sensor is determined as the current flowing through the first inductor.

6. The current measuring circuit as defined in claim 2, wherein, when the first switch and the fourth switch are turned on and the second switch and the third switch are turned off, and when the second switch and the third switch are turned on and the first switch and the fourth switch are turned off, the current measured by the current measuring sensor is ignored.

7. A current measuring circuit for a two phase electromotor, comprising:
first and second capacitors that are connected in series to each other;
first and second inductors that are connected in parallel to each other between the first and second capacitors connected in series to each other, and are supplied with two phase currents of the two phase electromotor, respectively;
a third switch that is connected to the second inductor; and
a current measuring sensor that is commonly provided among the second capacitor, the third switch, and the second inductor, and measures currents supplied to the first and second inductors.

8. The current measuring circuit as defined in claim 7, further comprising:
first and second switches that are connected in series to each other and are connected to the first inductor;
a fourth switch that is connected in series to the third switch,
wherein the first and third switches are connected in parallel to each other and are connected to the first capacitor, and
the second and fourth switches are connected in parallel to each other and are connected to the second capacitor.

9. The current measuring circuit as defined in claim 7, wherein the current measuring sensor measures a current that is obtained by subtracting a current according to a direct current voltage charged between the first and second capacitors by the current supplied to the second inductor.

10. The current measuring circuit as defined in claim 8, wherein the current measuring sensor measures the current flowing through the first inductor when the first switch and the third switch are turned on and the second s witch and the fourth switch are turned off, and measures an inverse current of the current flowing through the second inductor when the second switch and the fourth switch are turned on and the first switch and the third switch are turned off.

11. The current measuring circuit as defined in claim 10, wherein, when the second switch and the fourth switch are turned on and the first switch and the third switch are turned off, the inverse current of the current measured by the current measuring sensor is determined as the current flowing through the second inductor.

12. The current measuring circuit as defined in claim 8, wherein, when the first switch and the fourth switch are turned on and the second switch and the third switch are turned off, and when the second switch and the third switch are turned on and the first switch and the fourth switch are turned off, the current measured by the current measuring sensor is ignored.
